(19) United States
(12) Patent Application Publication
(10) Pub. No.: US 2006/0157792 A1
(43) Pub. Date: Jul. 20, 2006

(54) Laminated thin film capacitor and semiconductor apparatus

(75) Inventor: Shigeo Konushi, Yohkaichi-shi (JP)

Correspondence Address: HOGAN & HARTSON L.L.P., 500 S. GRAND AVENUE, SUITE 1900, LOS ANGELES, CA, 90071-2611, US

(73) Assignee: KYOCERA CORPORATION

(21) Appl. No.: 11/038,627

(22) Filed: Jan. 19, 2005

(51) Int. Cl. H01L 23/62

(52) U.S. Cl. 257/359

(57) ABSTRACT

The laminated thin film capacitor has the configuration in which the electrode layers of one polarity 2a to 2c and the electrode layers of the other polarity 4a and 4b are alternately laminated on a supporting substrate 1 with the corresponding thin film dielectric layers 3a to 3d being sandwiched therebetween. A layout region of the electrode layer 2c arranged relatively further from the supporting substrate among the electrode layers of one polarity 2a to 2c is encompassed in a layout region of the electrode layer 2b arranged relatively closer to the supporting substrate, and the layout region of the electrode layer 2b is encompassed in a layout region of the electrode layer 2a arranged even closer to the supporting substrate. With this configuration, deterioration of insulating characteristics and reliability due to the laminated layers can be restricted.

### BACKGROUND OF THE INVENTION

1. Field of the Invention

The present invention relates to a laminated thin film capacitor in which an electrode layer of one polarity and an electrode layer of the other polarity are alternately laminated on a supporting substrate with a thin film dielectric layer being sandwitched therebetween. The present invention relates to a semiconductor apparatus including the above laminated thin film capacitor.

2. Description of the Related Art

A capacitor is one of electronic components located in electronic equipment. The compact capacitor available for small-sized electronic equipment such as cellular phone has been now realized.

Today, it is highly expected that a capacitor will becomes lighter, thinner and more sophisticated as well as become smaller.

A laminated thin film capacitor having the configuration in which a thin film electrode layer and a thin film dielectric layer are alternately laminated on a supporting substrate with electrical insulating properties is a capacitor suited to make electronic components thinner.

However, a practicable laminated thin film capacitor cannot be produced only by reducing the thickness of the thin film dielectric layer and laminating the layers. Especially in terms of the reliability of the capacitor, it is a critical matter to ensure sufficient insulating properties.

Structurally, the laminated thin film capacitor is formed by adhering the electrode layer and the thin film dielectric layer alternately to the supporting substrate.

FIGS. 12(a) and 12(b) are an example of a conventional laminated thin film capacitor. FIG. 12(a) is a plan view and FIG. 12(b) is a cross-sectional view of the capacitor.

On a supporting substrate 21 are laminated an electrode layer of one polarity 22a, a thin film dielectric layer 23a, an electrode layer of the other polarity 24a, a thin film dielectric layer 23b, an electrode layer of one polarity 22b, a thin film dielectric layer 23c, an electrode layer of the other polarity 24b, a thin film dielectric layer 23d and an electrode layer of one polarity 22c in this order.

End parts of the electrode layers of one polarity 22a to 22c (collectively referred to as 22) extend beyond the thin film dielectric layers 23a to 23d (collectively referred to as 23) in the downward direction in the figure and a terminal unit 25 is disposed at the end parts. End parts of the electrode layers of the other polarity 24a and 24b (collectively referred to as 24) extend beyond the thin film dielectric layers in the upward direction in the figure and a terminal unit 26 is disposed at the end parts.

In such laminated thin film capacitor, the electrode layers 22 and 24 have the same width in the horizontal direction, thereby causing a step S on the border between the electrode layers 22 and 24. Accordingly, unless the electrode layers 22 and 24 are coated with the thin film dielectric layer 23 having much thicker than the electrode layers 22 and 24, a short-circuit between the electrode layers having different polarities and deterioration in insulating properties of the electrode layers are generated, thereby to undermine the reliability of the laminated thin film capacitor.

For ensuring the insulating properties and reliability for the laminated thin film capacitor, it is one of important issues how to address the step S.

As the number of the laminated layers is increased, the step S between the part containing electrode layers and the part containing no electrode layers becomes prominent (Theoretically, the step S corresponds to the value obtained by multiplying the thickness of the electrode by the number of the laminated layers). For this reason, there is the problem that it is difficult to ensure the thickness of the thin film dielectric layer for coating the step S and therefore sufficient insulating properties and reliability cannot be realized.

An object of the present invention is to provide a laminated thin film capacitor that prevents deterioration insulating properties and reliability due to the step between the part containing electrode layers and the part containing no electrode layers irrespective of the number of the laminated layers.

Another object of the present invention is to provide a semiconductor apparatus wherein the above laminated thin film capacitor is mounted.

### BRIEF SUMMARY OF THE INVENTION

The laminated thin film capacitor of the present invention is characterized by that a layout region of one electrode layer of any two electrode layers constituting the electrode layers of one polarity is encompassed in a layout region of the other electrode layer, and a layout region of one electrode layer of any two electrode layers constituting the electrode layers of the other polarity is encompassed in a layout region of the other electrode layer.

With the above-mentioned configuration, even when the number of laminated layers in the capacitance region is increased, a step in the thin film dielectric layer caused by the presence of thee electrode layer corresponds to a thickness of one electrode at the maximum, and therefore sufficient insulating properties and reliability as the laminated thin film capacitor can be ensured.

It may be configured so that among the electrode layers constituting the electrode layers of one polarity, a layout region of an electrode layer arranged further from the supporting substrate is encompassed in a layout region of an electrode layer arranged closer to the supporting substrate. That is, the electrode layer becomes smaller as it goes away from the supporting substrate and the upper electrode layer is encompassed in the lower electrode layer.

It may be also configured so that among the electrode layers constituting the electrode layers of the other polarity, as the electrode layer goes away from the supporting substrate, the upper electrode layer is encompassed in the lower electrode layer.

It may be configured so that among the electrode layers constituting the electrode layers of one polarity, a layout region of an electrode layer arranged closer to the supporting substrate is encompassed in a layout region of an electrode layer arranged further from the supporting substrate. That is, the electrode layer becomes larger as it goes away from the supporting substrate and the lower electrode layer is encompassed in the upper electrode layer.

Further, It may be also configured so that among the electrode layers constituting the electrode layers of the other polarity, as the electrode layer goes away from the supporting substrate, the lower electrode layer is encompassed in the upper electrode layer.

The first terminal unit and the second terminal unit can be formed at any location, for example, in the vicinity of the periphery of the electrode layer. In this case, it is possible to adopt the configuration in which each electrode layer constituting the electrode layers of one polarity has a first extended part that extends partially from the thin film dielectric layer and the first terminal unit is connected these first extended parts, and each electrode layer constituting the electrode layers of the other polarity has a second extended part that extends partially from the thin film dielectric layer and the second terminal unit is connected these second extended parts.

Further, the first terminal unit and the second terminal unit maybe formed within the electrode layer. In this case, it is possible to adopt the configuration in which within each electrode layer constituting the electrode layers of one polarity, the first terminal unit is connected to the electrode layer, and within each electrode layer constituting the electrode layers of the other polarity, the second terminal unit is connected to the electrode layer.

Furthermore, when the laminated thin film capacitor has a protective film that coats the thin film dielectric layer and openings so as to expose the first terminal unit and the second terminal unit, sufficient resistance to humidity can be ensured by this protective film.

The ESR (Equivalent Series Resistance) characteristic is also an important characteristic. Although the lower ESR is generally deemed to be more preferable, the capacitor cannot work effectively or even be adversely affected depending the installed position of the capacitor to the circuit or functions required for the capacitor when ESR is too low. Therefore, it is critical to control ESR to be a proper value.

Thus, when the volume resistivity of an uppermost electrode layer among the electrode layers is made smaller than that of the other electrode layers, a desired ESR characteristic can be obtained by controlling the film thickness of the uppermost electrode layer. That is, although the ESR characteristic of the laminated thin film capacitor generally varies depending on the number of laminated layers, the fluctuation depending on the number of laminated layers can be reduced by making the volume resistivity of the other electrode layers relatively large. Since influence of the uppermost electrode layer on the ESR characteristic becomes greater when the volume resistivity of only uppermost electrode layer is made smaller, the ESR characteristic can be easily controlled only by controlling the film thickness of the uppermost electrode layer.

The laminated thin film capacitor of the present invention has three capacitance-generating regions where an electrode layer of one polarity and an electrode layer of the other polarity are alternately laminated on a supporting substrate with a thin film dielectric layer being sandwiched therebetween, and the three capacitance-generating regions are arranged at the center and left and right thereof at predetermined intervals, and a thickness of the uppermost electrode layer of the central capacitance-generating region among the three capacitance-generating regions is different from that of the uppermost electrode layers of the left and right capacitance-generating regions. In the laminated thin film capacitor of the present invention, the impedance characteristic at the high-frequency side can be controlled by controlling the thickness of the uppermost electrode layer in the central capacitance-generating region and the impedance characteristic at the low-frequency side can be controlled by controlling the thickness of the uppermost electrode layers in the left and right capacitance-generating regions.

The present invention further relates to a semiconductor device including the laminated thin film capacitor described above.

### BRIEF DESCRIPTION OF THE DRAWINGS

FIG. 1(a) is a plan view of a laminated thin film capacitor of the present invention.

FIG. 1(b) is a cross-sectional view taken along the lines A-A of FIG. 1(a).

FIG. 2(a) is a pattern diagram of each electrode layer of one polarity of the laminated thin film capacitor in FIG. 1.

FIG. 2(b) is a pattern diagram of each electrode layer of the other polarity of the laminated thin film capacitor in FIG. 1.

FIG. 3(a) is a plan view of another laminated thin film capacitor of the present invention.

FIG. 3(b) is a cross-sectional view taken along the lines A-A of FIG. 3(a).

FIG. 4(a) is a plan view of another laminated thin film capacitor of the present invention.

FIG. 4(b) is a cross-sectional view taken along the lines A-A of FIG. 4(a).

FIG. 5(a) is a pattern diagram of each electrode layer of one polarity of the laminated thin film capacitor in FIG. 4.

FIG. 5(b) is a pattern diagram of each electrode layer of the other polarity of the laminated thin film capacitor in FIG. 4.

FIGS. 6(a) to 6(j) are views of another laminated thin film capacitor of the present invention, FIG. 6(a) is a plan view of the whole of the laminated thin film capacitor, FIG. 6(b) is a pattern diagram of an electrode layer of one polarity, FIG. 6(c) is a pattern diagram of a thin film dielectric layer, FIG. 6(d) is a pattern diagram of an electrode layer of the other polarity, FIG. 6(e) is a pattern diagram of a thin film dielectric layer, FIG. 6(f) is a pattern diagram of an electrode layer of one polarity, FIG. 6(g) is a pattern diagram of a thin film dielectric layer, FIG. 6(h) is a pattern diagram of an electrode layer of the other polarity, FIG. 6(i) is a pattern diagram of a protective film and FIG. 6(j) is a pattern diagram of a terminal base layer.

FIGS. 7(a) to 7(j) are views of another laminated thin film capacitor of the present invention, FIG. 7 (a) is a plan view of the whole of the laminated thin film capacitor, FIG. 7(b) is a pattern diagram of an electrode layer of one polarity, FIG. 7(c) is a pattern diagram of a thin film dielectric layer, FIG. 7(d) is a pattern diagram of an electrode layer of the other polarity, FIG. 7(e) is a pattern diagram of a thin film dielectric layer, FIG. 7(f) is a pattern diagram of an electrode layer of one polarity, FIG. 7(g) is a pattern diagram of a thin film dielectric layer, FIG. 7(h) is a pattern diagram of an electrode layer of the other polarity, FIG. 7(i) is a pattern diagram of a protective film and FIG. 7(j) is a pattern diagram of a terminal base layer.

FIG. 8(a) is a plan view illustrating an example of a laminated thin film capacitor of the present invention and FIG. 8(b) is a cross-sectional view taken along the lines A-A of FIG. 8(a).

FIG. 9(a) is a plan view illustrating an example of a laminated thin film capacitor of the present invention and FIG. 9(b) is a cross-sectional view taken along the lines A-A of FIG. 9(a).

FIG. 10 is a diagram of results of the impedance characteristic in the case where the thickness of an uppermost electrode layer in a central capacitance-generating region is varied.

FIG. 11 is a diagram of results of the impedance characteristic in the case where the thickness of uppermost electrode layers in left and right capacitance-generating regions is varied.

FIG. 12(a) is a plan view illustrating an example of a conventional laminated thin film capacitor and FIG. 12(b) is a cross-sectional view taken along the lines A-A of FIG. 12(a).

FIG. 13 is a pattern diagram of a semiconductor device wherein a semiconductor integrated circuit chip including the laminated thin film capacitor is mounted on a wiring board.

### DETAILED DESCRIPTION OF THE INVENTION

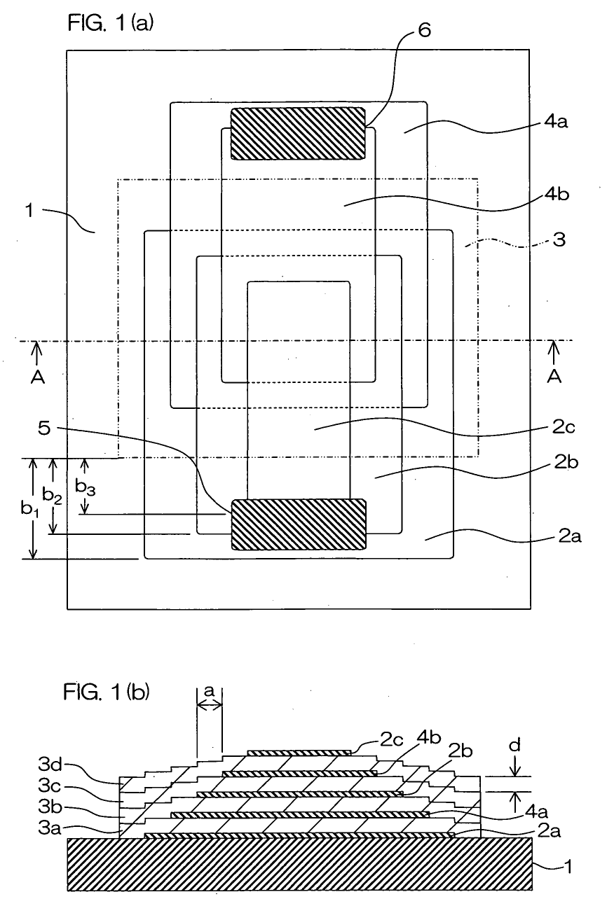

FIG. 1(a) is a perspective plan view of a laminated thin film capacitor in which five thin film electrode layers and four thin film dielectric layers each lying between the electrode layers are laminated and FIG. 1(b) is a cross-sectional view taken along the lines A-A of FIG. 1(a).

In the laminated thin film capacitor, an electrode layer 2a, a thin film dielectric layer 3a, an electrode layer 4a, a thin film dielectric layer 3b, an electrode layer 2b, a thin film dielectric layer 3c, an electrode layer 4b, a thin film dielectric layer 3d and an electrode layer 2c are laminated on a supporting substrate 1 in this order.

A protective film that coats the whole of the capacitor is not shown in these figures.

The electrode layer 2a, the electrode layer 2b and the electrode layer 2c constitute electrode layers of one polarity (collectively referred to as “electrode layers 2”) and the electrode layer 4a and the electrode layer 4b constitute electrode layers of the other polarity (collectively referred to as “electrode layers 4”). The four thin film dielectric layers 3a to 3d sandwiched between the electrode layers are collectively referred to as “thin film dielectric layers 3”.

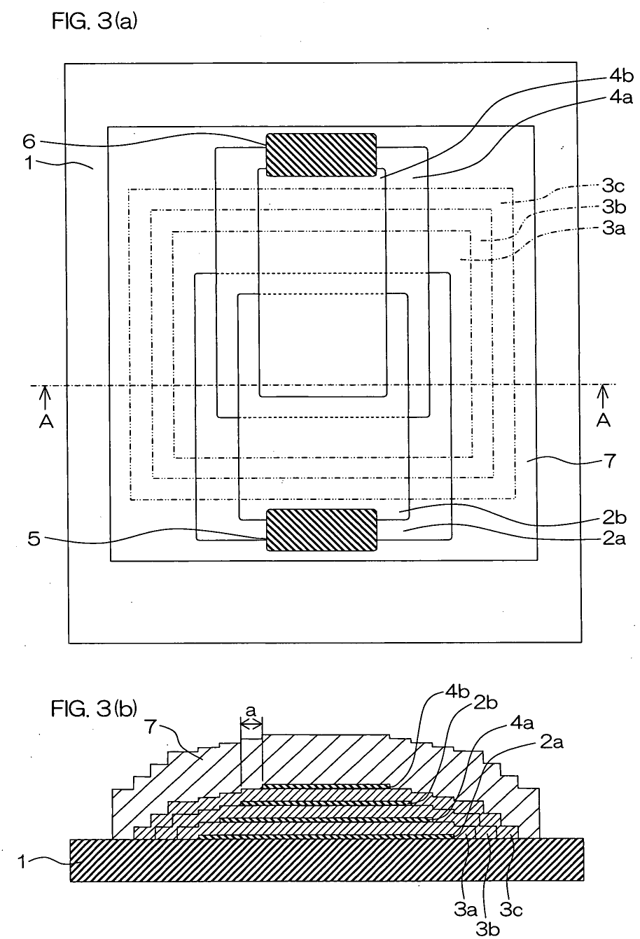

In FIG. 1(a), the thin film dielectric layers 3 are represented by chain double-dashed lines and peripheral parts of the layers 3a to 3d of the thin film dielectric layers 3 are cut vertically. As shown in FIG. 3(b) later, however, the peripheral parts of the layers 3a to 3d of the thin film dielectric layers 3 each may be stacked so as to have one-step.

As a matter of course, the number of the laminated layers in the thin film laminated capacitor is not limited to the number shown in FIG. 1(a) (i.e., 4 in dielectric layers).

As shown in FIG. 1(a), the lower end parts of the electrode layers of one polarity 2 extend beyond thin film dielectric layers 3 in the downward direction. An extended distance b1 of the electrode layer 2a, which is the closest to the supporting substrate, is longer than an extended distance b2 of the electrode layer 2b above the electrode layer 2a and the extended distance b2 of the electrode layer 2b is longer than an extended distance b3 of the above electrode layer 2c. In other words, as the electrode layers of one polarity go away from the supporting substrate 1, the extended distances b1, b2 and b3 between the electrode layers of one polarity and the corresponding thin film dielectric layers 3 become shorter in this order.

Similarly, as shown in FIG. 1(a), as the upper ends of the electrode layers of the other polarity 2 go away from the supporting substrate 1, the extended distances from the thin film dielectric layer 3 gradually become shorter.

The lower end parts of the extended electrode layers 2a to 2c are provided with a terminal unit 5 with being connected to each of the electrode layers 2a to 2c. The upper end parts of the extended electrode layers 4a and 4b are provided with a terminal unit 6 with being connected to each of the electrode layers 4a and 4b.

For example, the terminal units 5 and 6 can be made by forming a base conductive film on the uppermost electrode layers 2 and 4 according to the thin-film forming process and placing a bump member such as a solder on the base conductive film. This enables acquiring the internal units 5 and 6 with a high connecting reliability.

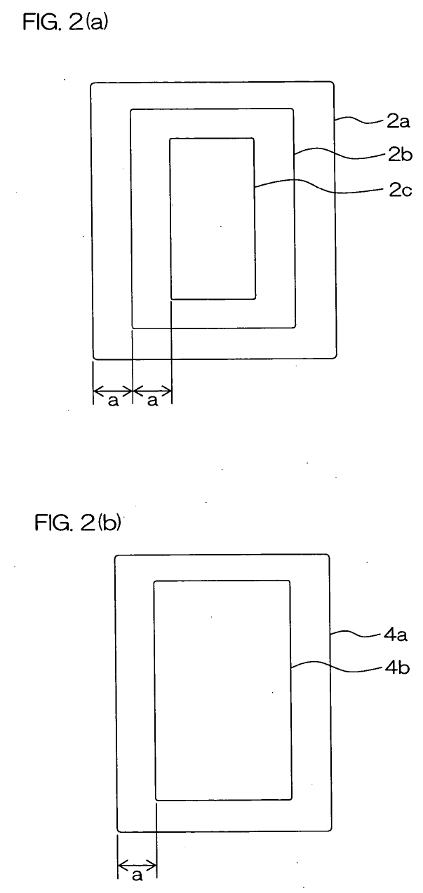

FIG. 2(a) is a schematic view showing the relationship among the electrode layers 2a to 2c in position and size. An area of the electrode layer 2b is set to be larger than that of the electrode layer 2c and the whole of the electrode layer 2c is arranged in the internal region of the electrode layer 2b. An area of the electrode layer 2a is set to be larger than that of the electrode layer 2b and the whole of the electrode layer 2b is arranged in the internal region of the electrode layer 2a.

FIG. 2(b) is a schematic view showing positional relationship between the electrode layers 4a and 4b. An area of the electrode layer 4a is set to be larger than that of the electrode layer 4b and the whole of the electrode layer 4b is arranged in the internal region of the electrode layer 4a.

As apparent from FIGS. 2(a) and 2(b), the periphery of one electrode layer 2 and the periphery of the other electrode layer 2 are arranged separately without intersecting or coinciding with each other and the periphery of one electrode layer 4 and the periphery of the other electrode layer 4 are arranged separately without intersecting or coinciding with each other.

As a result, in this embodiment, as shown in FIG. 1(b), a modest step on the whole is formed in the upper region of the thin film dielectric layers 3 irrespective of the number of laminated layers.

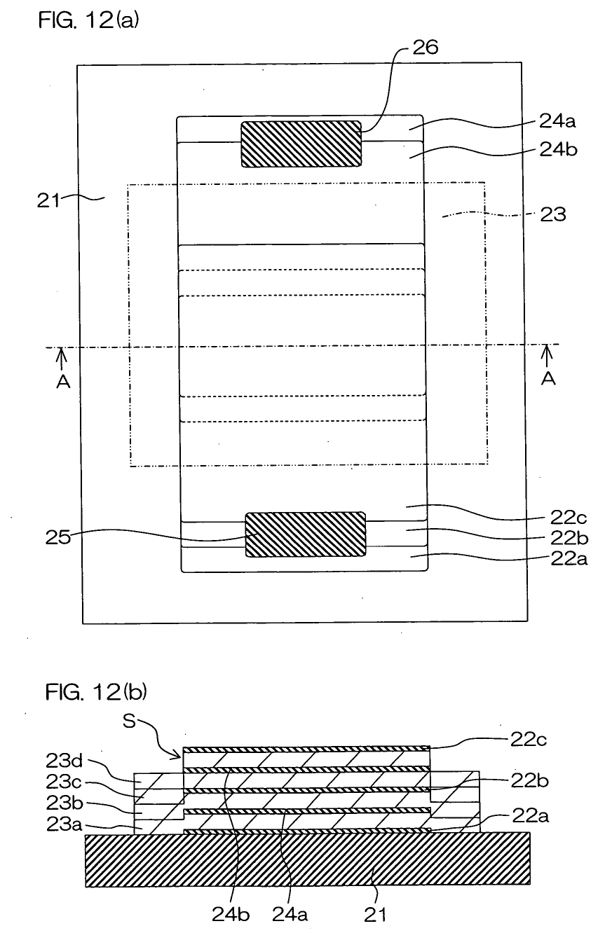

On the contrary, as shown in FIG. 12, conventionally, since the electrode layers 22 and 24 are formed by displacing the same mask for film formation in the vertical direction, both left and right sides of the peripheries of the electrode layers 22 and 24, for example, match with each other. For this reason, a step S generates on the left and right borders between the electrode layers 22 and 24. The step S becomes prominent as the number of the laminated thin film dielectric layers 3 is increased.

In this embodiment, no large step occurs in the upper region of the laminated thin film dielectric layers 3 irrespective of the number of laminated thin film dielectric layers 3.

Therefore, the insulating properties of the capacitor do not deteriorate. Thus, the capacitor becomes resistant to deterioration due to insulation, resulting in improvement in the reliability.

As shown in FIG. 2(a), a distance between the periphery of the electrode layer 2a and the periphery of the electrode layer 2b parallel to the electrode layer 2a and a distance between the periphery of the electrode layer 2b and the periphery of the electrode layer 2c parallel to the electrode layer 2b each are represented by “a”. As shown in FIG. 2(b), a distance between the periphery of the electrode layer 4a and the periphery of the electrode layer 4b parallel to the electrode layer 4a is represented by “a”. The plurality of distances “a” may be either same or different.

Given that the thickness of the electrode layers 2, 4 is t, it is desirable that t and the distance between the peripheries of the electrode layers 2, 4 “a” satisfies the following relationship:
20 t≦a≦400 t

When the distance a is less than 20 t, an angle of the step formed in the upper region of the thin film dielectric layers 3 becomes steep and the problem as observed with the conventional art occurs. When the distance a is equal to or more than 20 t, the angle of the step formed in the upper region of the thin film dielectric layers 3 becomes gentle. However, when the distance a exceeds 400 t, the area occupied by the capacitor becomes larger to ensure the capacitance of the capacitor.

Desirably, the thickness d of the thin film dielectric layers 3 and the thickness t of the electrode layers 2 and 4 satisfy the following relationship:
3 t≦d

When the relationship is satisfied, the step generated in the upper region of the thin film dielectric layers 3 becomes smaller and the insulating properties of the capacitor do not deteriorate. When the thickness d is less than 3 t, a steep step generates in the upper region of the thin film dielectric layers 3 based on the thickness t of the electrode layers 2 and 4. As a matter of course, an actual value of the thickness d is determined depending on the capacitance of the capacitor, the conductivity of the thin film dielectric layers 3, areas of the electrode layers 2 and 4 and so on.

FIG. 3(a) is a plan view of a laminated thin film capacitor in which three capacitance regions having a terminal unit are laminated and FIG. 3(b) is a cross-sectional view taken along the lines A-A of FIG. 3(a).

This laminated thin film capacitor has the substantially same configuration as the laminated thin film capacitor in FIG. 1(a).

This laminated thin film capacitor is different from the laminated thin film capacitor in FIG. 1(a) in that the peripheral parts of the layers 3a to 3d of the thin film dielectric layers 3 are cut vertically in the laminated thin film capacitor in FIG. 1(a), while the peripheral parts of the thin film dielectric layers 3a to 3c are laminated in a stepped condition.

In the laminated thin film capacitor in FIG. 3(a), a protective film 7 is shown. The protective film 7 has openings at positions where the terminal units 5 and 6 are exposed. The protective film 7 is formed so as to coat all of the dielectric layers 3. The protective film is desirably an inorganic film made of SiOx, SiNx and the like having a low moisture permeance factor and may be also an organic film made of benzocyclobutene (BCB resin) and polyimide resin and the like. Alternatively, a plurality of films may be combined to ensure further reliability.

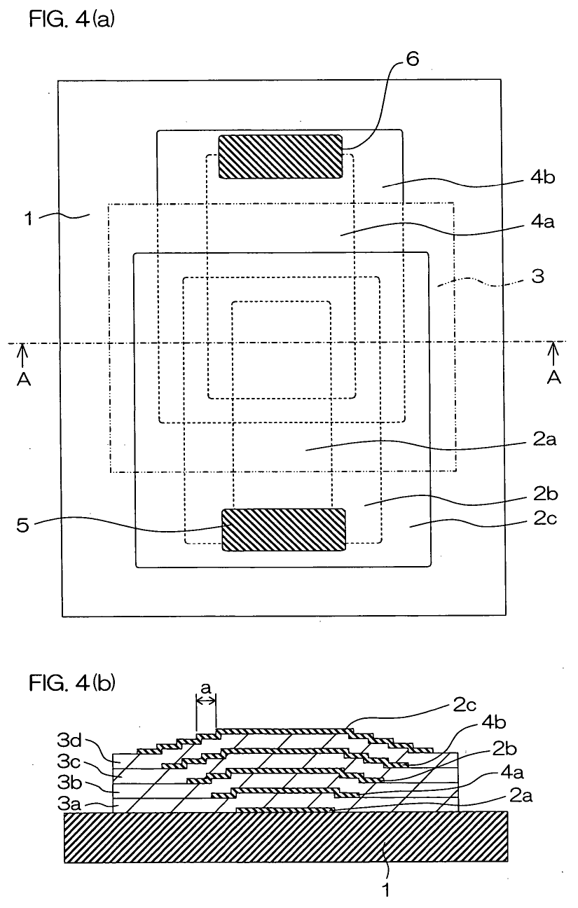

FIG. 4(a) is a plan view showing another embodiment of a laminated thin film capacitor of the present invention and FIG. 4(b) is a cross-sectional view taken along the lines A-A of FIG. 4(a).

While the laminated thin film capacitor in FIGS. 1(a) and 1(b) is configured so that the upper electrode layer is formed within the layout region of the lower electrode layer of the same polarity, the laminated thin film capacitor in this embodiment has the inverted configuration in which the lower electrode layer is formed within the layout region of the upper electrode layer of the same polarity. The electrode layers and the thin film dielectric layers are designated by the same reference numerals as FIG. 1.

In the laminated thin film capacitor in FIGS. 4(a) and 4(b), the electrode layer 2a, the electrode layer 4a, the electrode layer 2b, the electrode layer 4b and the electrode layer 2c are alternately laminated in this order from the side of the supporting substrate 1 and the film dielectric layers 3a to 3d each are intervened between the corresponding electrode layers.

The terminal unit 5 is disposed at the end parts of the extended electrode layers 2 and the terminal unit 6 is disposed at the end parts of the extended electrode layers 4.

As shown in FIG. 5(a), for the electrode layers 2 of one polarity, the lowermost electrode layer 2a viewed from the supporting substrate 1 is set to be smaller than the above electrode layer 2b. That is, the electrode layer 2b is arranged so as to encompass the layout region of the electrode layer 2a completely. The electrode layer 2b is set to be smaller than the above electrode layer 2c. That is, the electrode layer 2c is arranged so as to encompass the layout region of the electrode layer 2b completely.

For the electrode layers 4 of the other polarity, as shown in FIG. 5(b), the lowermost electrode layer 4a viewed from the supporting substrate 1 is set to be smaller than the above electrode layer 4b. That is, the electrode layer 4b is arranged so as to encompass the layout region of the electrode layer 4a completely.

Thus, in the laminated thin film capacitor shown in FIGS. 4(a) and 4(b), the peripheries of the electrode layers 2 and 4 are arranged so as not to intersect with each other both in the vertical and horizontal directions, and the electrode layers 2 and 4 and the thin film dielectric layers 3 form the modest step based on the thickness of the electrode layers 2 and 4.

As a matter of course, the number of the laminated layers in the thin film laminated capacitor is not limited to the number shown in FIG. 4(a). As shown in FIG. 3(b), the peripheral parts of the thin film dielectric layers 3a to 3d each may be stacked so as to have a step. Although not shown in FIG. 4(a), it is preferable to coat the whole of the laminated thin film capacitor with a protective film.

The laminated thin film capacitor in FIG. 1(a) to FIG. 5(b) has the configuration in which the upper and lower extended end parts of the electrode layers are provided with the terminal unit. However, the present invention can also apply to the configuration in which the electrode terminal is disposed within the electrode layers.

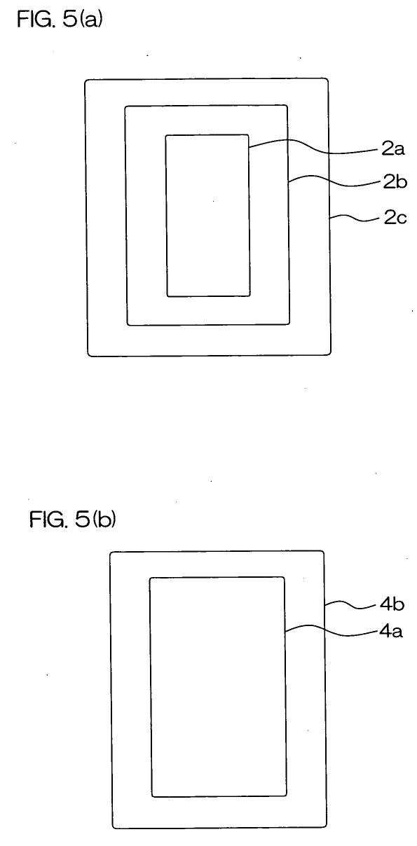

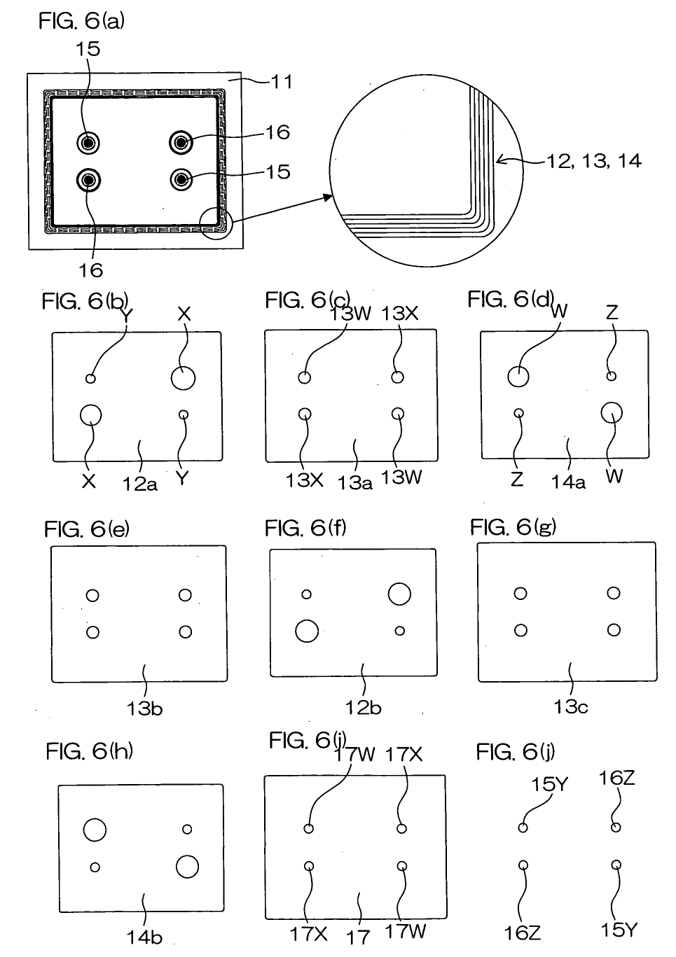

FIGS. 6(a) to 6(j) are schematic views of a laminated thin film capacitor of this type. This laminated thin film capacitor is a laminated thin film capacitor with low inductance that terminal units 15 and 16 are formed at plural positions within the layout region of electrode layers of one polarity 12 and electrode layers of the other polarity 13.

In this laminated thin film capacitor, an electrode layer 12a, a thin film dielectric layer 13a, an electrode layer 14a, a thin film dielectric layer 13b, an electrode layer 12b, a thin film dielectric layer 13c, an electrode layer 14b and a protective film 17 are laminated on a supporting substrate 11 in this order.

The electrode layer 12a and the electrode layer 12b constitute electrode layers of one polarity (collectively referred to as “electrode layers 12”) and the electrode layer 14a and the electrode layer 14b constitute electrode layers of the other polarity (collectively referred to as “electrode layers 14”). The three thin film dielectric layers 13a to 13c sandwiched between the electrode layers are collectively referred to as “thin film dielectric layers 13”.

FIG. 6(a) is a plan view of the laminated thin film capacitor with the protective film 17 being omitted. The four terminal units 15 and 16 in total are arranged in two columns and two rows. As shown in an enlarged view of the figure, a step is formed along the lamination consisting of the electrode layers 12 and the thin film dielectric layers 13.

That is, in this laminated thin film capacitor, the peripheral shape of each of the electrode layers 12 and 14 is formed so as to become smaller gradually toward the upper layers from the supporting substrate with a displacement of 20 times as large as the thickness t of the electrode or more. Such configuration of the electrode layers is the same as the configuration shown in FIG. 1 and FIG. 3. In doing so, the peripheries of all layers 2 and 4 as well as the electrode layers 2 of the same polarity and the electrode layers 4 of the same polarity are prevented from intersecting with each other and the peripheral parts of the thin film dielectric layers 3 and the electrode layers 2 and 4 can constitute the modest staged step.

FIGS. 6(b) and 6(f) are electrode pattern diagrams of the electrode layers of one polarity 12a and 12b, respectively. In FIGS. 6(b) and 6(f), relatively large circles X in the upper right and the lower left of each electrode pattern 12 are through holes formed so as not to cause a short-circuit with conductors 16 that connect the electrode layers of the other polarity 14 with each other and relatively small circles Y in the upper left and the lower right of each electrode pattern are conductor sites that connect the electrode layers of one polarity 12 with each other. These conductor sites correspond to the locations at which a terminal base layer pattern 15Y described later is formed.

FIGS. 6(d) and 6(h) are electrode pattern diagrams of the electrode layers of the other polarity 14a and 14b, respectively. In FIGS. 6(d) and 6(h), relatively large circles W in the upper left and the lower right of each electrode pattern are through holes formed so as not to cause a short-circuit with conductors 15 that connect the electrode layers of one polarity 12 with each other and are larger than the above-mentioned conductor site Y. Smaller circles Z in the upper right and the lower left of each electrode pattern show conductor sites that connect the electrode layers of the other polarity 14 with each other, are located within the above-mentioned through holes X and correspond to locations at which a terminal base layer pattern 16Z is formed.

FIGS. 6(c), (e) and (g) are patterns of the dielectric layers 13a, 13b and 13c, respectively. The dielectric layer 13 is provided with through holes 13X and 13W so as to correspond to regions at which the terminal units 15 and 16 are formed.

FIG. 6(i) shows a pattern of the protective film 17 that covers the patterns of all dielectric layers 3 and through holes 17X and 17W are formed so as to correspond to the regions at which the terminal units 15 and 16 are formed.

FIG. 6(j) shows the terminal base layers 15Y and 16Z formed at the locations corresponding to the through holes of each of the thin film dielectric layers 13 for connecting the electrode layers of one polarity 12 to the terminal units 15 and the electrode layers of one polarity 14 to the terminal units 16.

Although the terminal units 15 and 16 are formed in two rows in a diagonal or zigzag manner in the laminated thin film capacitor shown in FIGS. 6(a) to 6(j), the present invention is not limited to the number and arrangement.

The number of rows may be one or more. Further, any number of terminals in the row may be formed in light of capacitance value generated in the capacitance region and inductance elements.

The terminal unit 15 and the terminal unit 16 may be formed alternately in each row. In addition, the terminal units of the same polarity may be arranged in even-numbered row and odd-numbered row in a zigzag manner.

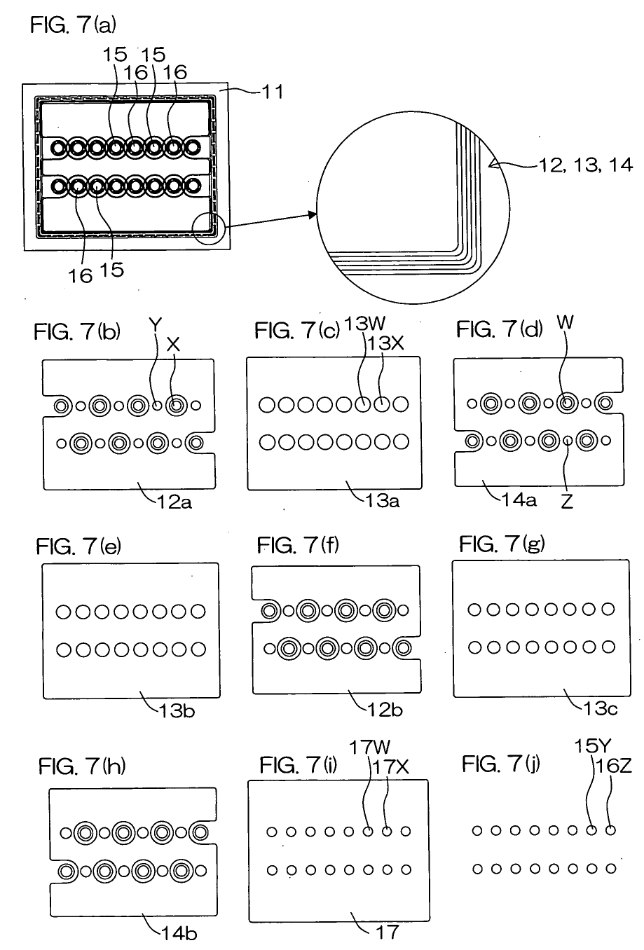

As an example, a laminated thin film capacitor having 16 terminals (eight terminals in each of two rows) is shown in FIGS. 7(a) to 7(j). In FIGS. 7(a) to 7(j), the same reference numerals are assigned to the same elements as in FIGS. 6(a) to 6(j).

This laminated thin film capacitor is a laminated thin film capacitor with low inductance that the terminal units 15 and 16 are formed at plural positions within the layout region of the electrode layers of the other polarity 12 and electrode layers of the other polarity 13.

FIG. 7(a) is a plan view of the laminated thin film capacitor with the protective film being omitted. The sixteen terminal units 15 and 16 in total are arranged in two columns and eight rows. At the peripheral parts of the thin film dielectric layers 13, a step is formed along the lamination of the thin film dielectric layers 13.

That is, also in this laminated thin film capacitor, the peripheral shape of each electrode layer 12 and 14 is formed so as to become smaller gradually toward the upper layers from the supporting substrate. Such configuration of the electrode layers is the same as the configuration shown in FIGS. 1, 3 and 6. In doing so, the peripheries of all layers 2 and 4 as well as the electrode layers 2 of the same polarity and the electrode layers 4 of the same polarity are prevented from intersecting with each other and the peripheral parts of the thin film dielectric layers 3 and therefore the peripheral parts of the thin film dielectric layers and the electrode layers 2 and 4 can constitute the modest staged step.

FIGS. 7(b) and 7(f) are electrode pattern diagrams of the electrode layers of one polarity 12a and 12b, respectively. In FIGS. 7(b) and 7(f), relatively large circles X in the upper right and the lower left of each electrode pattern 12 are through holes formed so as not to cause a short-circuit with the conductors 16 that connect the electrode layers of the other polarity 14 with each other and relatively small circles Y in the upper left and the lower right of each electrode pattern are conductor sites that connect the electrode layers of one polarity 12 with each other. These conductor sites correspond to the locations at which the terminal base layer pattern 15Y is formed.

FIGS. 7(d) and 7(h) are electrode pattern diagrams of the electrode layers of the other polarity 14a and 14b, respectively. In FIGS. 7(d) and 7(h), relatively large circles W in the upper left and the lower right of each electrode pattern are through holes formed so as not to cause a short-circuit with conductors 15 that connect the electrode layers of one polarity 12 with each other and are larger than the above-mentioned conductor sites Y. Smaller circles Z in the upper right and the lower left of each electrode pattern show conductor sites that connect the electrode layers of the other polarity 14 with each other, are located within the above-mentioned through holes X and correspond to locations at which the terminal base layer pattern 16Z is formed.

FIGS. 7(c), 7(e) and 7(g) are patterns of the dielectric layers 13a, 13b and 13c, respectively. The dielectric layer 13 is provided with through holes 13X and 13W so as to correspond to regions at which the terminal units 15 and 16 are formed.

FIG. 7(i) shows a pattern of the protective film 17 that covers the patterns of all dielectric layers 3 and through holes 17X and 17W are formed so as to correspond to the regions at which the terminal units 15 and 16 are formed.

FIG. 7(j) shows the terminal base layers 15Y and 16Z formed at the locations corresponding to the through holes of each of the thin film dielectric layers 13 for connecting the electrode layers of one polarity 12 to the terminal units 15 and the electrode layers of one polarity 14 to the terminal units 16.

Next, an example in which conductivity of the electrode layers of the laminated thin film capacitor of the present invention is varied will be described in detail referring to figures.

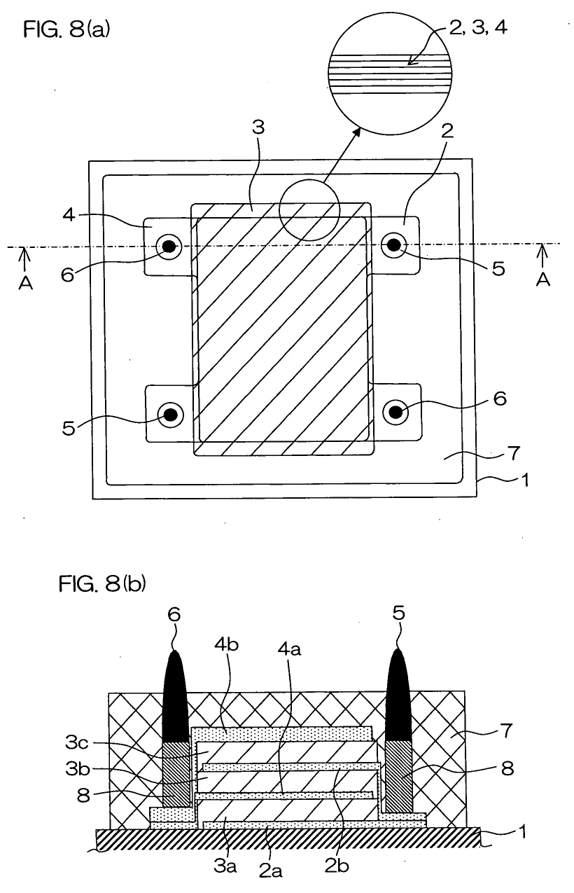

FIGS. 8(a) and 8(b) shows a laminated thin film capacitor in which three capacitance regions are laminated. FIG. 8(a) is a plan view of the laminated thin film capacitor and FIG. 8(b) is a cross-sectional view taken along the lines A-A of FIG. 8(a).

As shown in FIGS. 8(a) and 8(b), this laminated thin film capacitor is configured so that the electrode layer and the dielectric layer are laminated alternately on the supporting substrate 1 with the electrode layer being sandwiched between the electrode layers. Specifically, this laminated thin film capacitor has the configuration in which the electrode layer of one polarity 2a, the thin film dielectric layer 3a, the electrode layer of the other polarity 4a, the thin film dielectric layer 3b, the electrode layer of one polarity 2b, the thin film dielectric layer 3c and the electrode layer of the other polarity 4b are laminated on a supporting substrate 1 in this order. The capacitance regions are laminated by sandwiching the thin film dielectric layer 3 (collectively referred to as 3) between the electrode layer of one polarity 2 (collectively referred to as 2) and the electrode layer of the other polarity 4 (collectively referred to as 4).

The end part of the electrode layer of one polarity 2 extends beyond the dielectric layer 3 to the right in the figure and the terminal unit 5 is disposed on the extended end part through a terminal electrode layer 8. The end part of the electrode layer of the other polarity 4 extends beyond the dielectric layer 3 to the left in the figure and the terminal unit 6 is disposed on the extended end part through the terminal electrode layer 8.

Further, the protective film 7 with openings to expose the terminal units 5 and 6 is formed so as to the electrode layers 2 and 4, the dielectric layers 3, and the terminal electrode layers 8.

An uppermost electrode layer is the electrode layer of the other polarity 4b and the electrode layer is made of a material having a volume resistively of 3.0×10⁻⁸ Ωm or less under 100° C.

The electrode layers other than the uppermost layer, that is, the electrode layers of one polarity 2a and 2b and the electrode layers of the other polarity 4a are made of a material having a volume resistivity ranging from 10.0×10⁻⁸ Ωm to 20.0×10⁻⁸ Ωm under 100° C.

By configuring the electrode layers with these materials, the ESR characteristic of the capacitor can be controlled easily.

The ESR characteristic is affected by parallel connection of the electrode layers depending on the number of the laminated layers, the thickness of the electrode layer and volume resistivity specific to material. The number of the laminated layers is determined to obtain a desired capacitance efficiently. When the thickness of the electrode layer is much greater than that of the dielectric layer, deterioration due to insulation may be caused, and when the thickness of the electrode layer is too small, a film cannot be formed and thus the scope of control is limited. Therefore, for the control of ESR, it is effective to change the material of the electrode layer.

However, from the viewpoint of stability and economical efficiency, it is undesirable to change materials of all electrode layers for obtaining a desired ESR.

Consequently, a parallel effect of the electrode layers depending on the number of the laminated layers is utilized by making the electrode layers other than the uppermost layer with a material having a relatively high volume resistivity to ensure certain degree of ESR. Simultaneously, the uppermost electrode layer of high degree-of-freedom in design of film thickness is made of a material having a low volume resistivity. This enables controlling ESR to a desired value.

The reason why the volume resistivity of the electrode layers other than the uppermost layer is made to range from 10.0×10⁻⁸ Ωm to 20.0×10⁻⁸ Ωm under 100° C. is as follows: in the event that the volume resistivity exceeds the range, ESR due to lamination of the electrode layers becomes large and therefore a desired ESR cannot be obtained even when volume resistivity of the uppermost electrode layer is made to be smaller. On the other hand, in the event that the volume resistivity falls below the range, ESR due to lamination of the electrode layers becomes small and therefore a desired ESR cannot be obtained even when volume resistivity of the uppermost electrode layer is made to be larger. Moreover, for the design in consideration of actual operating environment, the volume resistivity under 100° C. is adopted, because the operating environment of passive components loaded on an IC circuit as in the technical field of the present invention is deemed to be a high-temperature region of about 100° C.

Among possible materials, Pt is the most desirable one since Pt cannot be oxidized in the formation of the dielectric layer and has stable electrical characteristics. By using Pt as the material for the electrode layers other than the uppermost layer, there is no possibility of oxidizing in the formation of the dielectric layer, thereby to obtain stable electrical characteristics.

The reason why the volume resistivity of the uppermost electrode layer is set to be 3.0×10⁻⁸ Ωm or less under 100° C. is because acquiring a desired ESR becomes difficult with the volume resistivity more than 3.0×10⁻⁸ Ωm.

Since Au, Cu and Ag of high purity are easily available, these metals are desirable as the material of the uppermost electrode layer.

Although the shape of the terminal units 5 and 6 is not limited specifically, in the case where low inductance is required, the bump shape shown in the figures is desirable and further a height less than 0.1 mm is desirable. When these terminal units are formed of a solder bump having a height less than 0.1 mm, inductance caused by the solder bump can be lowered.

Moreover, although the number of the terminal units 5 and 6 are four in total in the examples, the number is not limited and in the case where even further lower inductance is required, the number should be increased.

In the fields where control of the ESR characteristic of the laminated thin film capacitor is required as in the present invention, the laminated thin film capacitor is used for bypass of high-frequency noise or prevention of fluctuation of power supply voltage. In such fields, a low inductance characteristic is required. To improve effects of the present invention, it is desirable that the laminated thin film capacitor has an inductance of 20 pH or lower.

Next, an example in which the thickness of the electrode layers of the laminated thin film capacitor of the present invention is varied will be described in detail referring to figures.

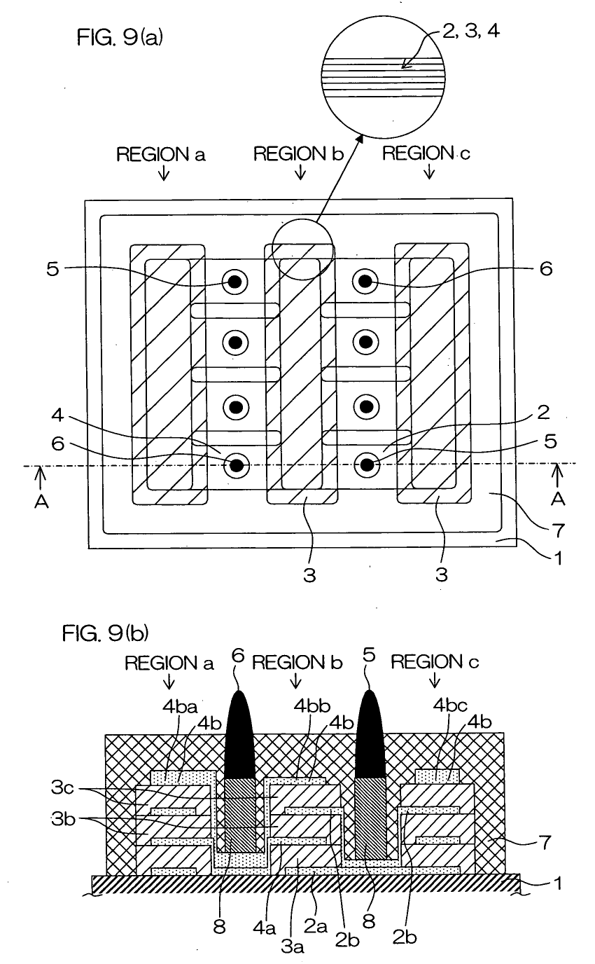

FIGS. 9(a) and 9(b) show a laminated thin film capacitor in which the dielectric layer is sandwiched between the electrode layer of one polarity and the electrode layer of the other polarity and three capacitance regions are located in parallel.

FIG. 9(a) is a plan view of the laminated thin film capacitor and FIG. 9(b) is a cross-sectional view taken along the lines A-A of FIG. 9(a). The three capacitance-generating regions are defined as a region a, a region b and a region c from the left in the figures.

In the laminated thin film capacitor of the present invention, the electrode layer of one polarity 2a, the dielectric layer 3a, the electrode layer of the other polarity 4a, the dielectric layer 3b, the electrode layer of one polarity 2b, the dielectric layer 3c and the electrode layer of the other polarity 4b are laminated on the supporting substrate 1 in this order. That is, the electrode layer of one polarity 2 and the electrode layer of the other polarity 4 are alternately laminated with the thin film dielectric layer being sandwiched therebetween, whereby that three capacitance-generating regions are formed and placed in parallel.

The end part of the electrode layer of one polarity 2 extends beyond the dielectric layer 3 partially and the terminal unit 5 is disposed on the extended end part through the terminal electrode layer 8. The end part of the electrode layer of the other polarity 4 extends beyond the dielectric layer 3 partially and the terminal unit 6 is disposed on the extended end part through the terminal electrode layer 8.

Further, the protective film 7 with openings to expose the terminal units 5 and 6 is formed so as to coat the electrode layers 2 and 4, the dielectric layers 3, and the terminal electrode layers 8.

In FIGS. 9(a) and 9(b), the thickness of the uppermost electrode layer 4b in the capacitance-generating region b located in the center (hereinafter referred to as electrode layer 4bb) is different from that of the uppermost electrode layers 4b in the capacitance-generating regions a and c located in the left and right (hereinafter referred to as electrode layer 4ba and 4bc).

By controlling the thickness of the electrode layer 4bb independently of the thickness of the electrode layers 4ba and 4bc, the impedance characteristic of a desired frequency domain can be controlled. Especially, the thickness of the electrode layer 4bb located at the top of the central capacitance-generating region b among the three capacitance-generating region a, b and c is set to be thicker or thinner than that of the electrode layers 4ba and 4bc located at the top of the left and right capacitance-generating regions by 10% or more in consideration of control range of film thickness according to a thin-film forming method (5 to 10%).

Because of the configuration of this laminated thin film capacitor, the above-mentioned control is effective. Since this laminated thin film capacitor-has the configuration in which the three laminated capacitance-generating regions a, b and c are connected in parallel, the impedance characteristics taken from the common terminal units 5 and 6 become combined characteristics of each impedance characteristic of these three laminated capacitance-generating regions a, b and c. Accordingly, by controlling the thickness of the electrode layer 4bb independently of that of the electrode layers 4ba and 4bc, each impedance characteristic, especially the ESR characteristic can be varied. By combining them, the impedance characteristic in a desired frequency domain can be controlled.

Desirably, the uppermost electrode layer 4b is made of a material having a volume resistively of 3.0×10⁻⁸ Ωm or less under 100° C. and the electrode layers 2a, 2b and 4a other than the uppermost layer are made of a material having a volume resistivity ranging from 10.0×10⁻⁸ Ωm to 20.0×10⁻⁸ Ωm under 100° C. Such configuration of materials can control the ESR characteristic of the capacitor more easily.

In the fields where control of the impedance characteristic or ESR characteristic is required as in the present invention, the laminated thin film capacitor is used for bypass of high-frequency noise or prevention of fluctuation of power supply voltage. In such fields, a low inductance characteristic is required. The inductance characteristic can be controlled by controlling shape, arrangement and quantity of the terminal units 5 and 6.

Generally, shape, arrangement and quantity of the terminal units 5 and 6 are not limited specifically. However, in the case where a low inductance characteristic is required as described above, connecting length of the terminal units should be shortened. Accordingly, as the shape of the terminal units 5 and 6, the bump shape shown in the figures is desirable and further a height of 0.1 mm or less is desirable.

Moreover, the arrangement in which the terminal unit 5 connecting the electrode layers of one polarity and the terminal unit 6 connecting the electrode layers of the other polarity are aligned alternately brings about the advantageous effect of lowering inductance of the capacitor. Especially, impedance in high-frequency domain can be reduced. This enables keeping small impedance constant in a wide frequency domain. Although the number of the terminal units 5 and 6 is four in total in FIG. 9, the inductance becomes lower as the number is increased.

Especially when the thickness of each dielectric layer is three times as large as the largest thickness of the electrode layers other than the uppermost layer or more, an excellent coating property of the dielectric layer to the end part of the electrode layer can be obtained, thereby to eliminate the possibility of deterioration due to insulation. As a result, product reliability can be ensured.

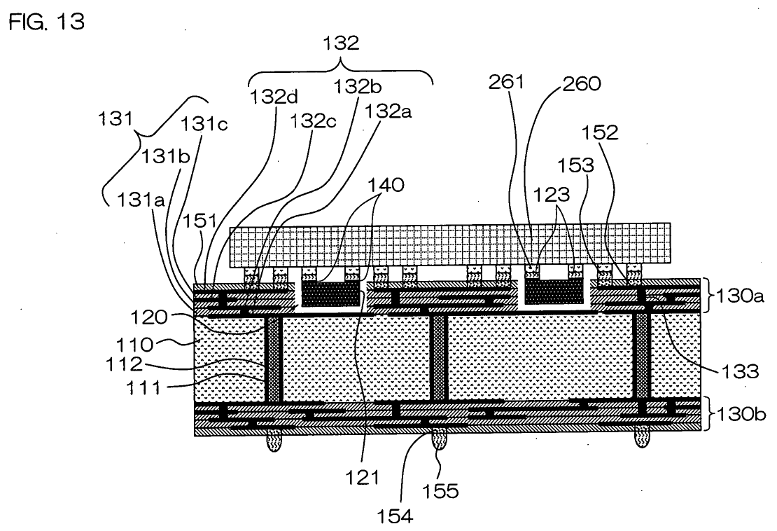

Next, cross-sectional views of semiconductor apparatus which includes a semiconductor integrated circuit device mounted on a wiring board (hereinafter simply referred to as “wiring board”) provided with a laminated thin film capacitor of FIGS. 8 and 9 is shown in FIG. 13.

The wiring board comprises a core substrate 110 serving as base and a build-up, layer 130a thereon including wiring conductor layers and insulator layers alternately stacked.

The build-up layer 130a is formed with cavities 120 on whose bottom surfaces decoupling laminated thin film capacitors (hereinafter, simply referred to as “capacitor”) 121 are disposed. The capacitor 121 is a thin and flat chip provided with electrode terminals 140 to be connected to a semiconductor integrated circuit chip on its top surface, and electrode terminals to be connected to the build-up 130a on its back surface.

The semiconductor component comprises the wiring board shown in FIG. 13, and a semiconductor integrated circuit chip 260 is placed on the electrode terminals on the top surfaces of the capacitors 121 and the build-up layer 130a, in which the semiconductor integrated circuit chip 260 is electrically connected to the capacitors 121.

As shown in FIG. 13, the wiring board comprises a core substrate 110, a build-up layer 130a formed on the surface side of the wiring board, and a build-up layer 130b formed on the back side of the wiring board. The build-up layer 130a on the surface side of the wiring board wiring includes conductor lines 132 (132a, 132b, 132c, 132d) constituting a first wiring conductor and interlayer insulation layer 131 (131a, 131b, 131c). The build-up layer 130b on the back side of the wiring board has a construction similar to that of the build-up layer 130a on the surface side of the wiring board. In the build-up layer 130a on the surface side of the wiring board, the cavities 120 for accommodating the capacitors 121 are formed.

The material for the core substrate 110 may be an inorganic material such as ceramics, AlN or the like, or a resin material generally used for printed wiring boards, including glass epoxy resin-impregnated base material, phenol resin-impregnated base material or the like. The material for the interlayer insulation layers 131 may be a thermosetting resin such as epoxy-based resin, thermoplastic resin, photosensitive resin, a composite of thermosetting resin and thermoplastic resin, a composite of photosensitive resin and thermoplastic resin or the like.

As the material for the wiring conductor layer 132, commonly used conductor materials such as Cu, Al, Ni—Cu alloys, Cu—Al alloys may be used.

The capacitor 121 is disposed so that the upper main surface faces the opening (upper side) and the lower main surface faces the bottom surface of the cavity 120.

Via hole conductors 133 penetrating the interlayer insulation layer 131 are formed in the interlayer insulation layer 131 of the build-up layer 130a, and the upper and lower wiring conductor layers 132 are electrically connected through the via hole conductors. A solder resist layer 151 comprising an insulator is formed on the wiring conductor layer 132 that is formed in an upper most portion of the build-up layer 130a. The solder resist layer 151 is formed with small apertures, in which electrode terminals 152 connected to the wiring conductor layer 132d are buried.

Solder balls 123 used for mounting a semiconductor integrated circuit chip 260 are formed on the electrode terminals in the upper main surface of the body of the capacitor 121.

Solder balls 153 serving as a connection portion for mounting the semiconductor integrated circuit chip 260 are formed on the electrode terminals 152 in the build-up layer 130a.

In the wiring board, also on the opposite side of the surface on which the semiconductor integrated circuit chip 260 is mounted, the build-up layer 130b is provided as mentioned above.

The build-up layer 130b is connected to the build-up layer 130a through interior through-hole wiring layers 111 formed in the core substrate 110. Electrode terminals 154 formed in the build-up layer 130b are electrically connected to a motherboard that is not shown through solder balls 155 serving as a connection portion.

In the wiring board, the capacitor 121 is disposed within the cavity 120, in which the bottom area of the cavity 120 is made larger than the cross section area of the capacitor 121 to be accommodated therein. This is because the machining accuracy for the cavities 120 is lower than the positioning accuracy for mounting the semiconductor integrated circuit chip 260.

The depth of the cavity 120 is determined according to the thickness of the capacitor 121 to be accommodated therein. The depth of the cavity 120 is preferably determined so that the upper main surface of the capacitor 121 and the upper main surface of the solder resist layer 151 (the upper end surface of the electrode terminals 152 in the build-up layer 130a) are flush with each other.

The adhesive used for bonding the back surface of the capacitor and the bottom surface of the cavity 120 together is preferably of thermoplastic nature that permits self-alignment during the mounting of a semiconductor component on the wiring board.

Electrode terminals 261 provided on the back surface of a semiconductor integrated circuit chip 260 are connected to electrode terminals 152 of the wiring board through solder balls 153 in the wiring board. The electrode terminals 261 provided on the back surface of the semiconductor integrated circuit chip 260 are electrically connected to electrode terminals of capacitors 121 through solder balls 123.

Meanwhile, the wiring board described so far may be embodied as a wiring board in which electrode terminals are present on the lower main surface of the body of the capacitor 121. In such a case, there are electrode terminals on the lower surface of the capacitor 121 that are connected to electrode terminals of the semiconductor integrated circuit chip 260 and electrode terminals of the build-up layer 130a. In such a case, the capacitor 121 comprises a plurality of dielectric layers and electrode layers interposed among the dielectric layers. Though-holes penetrating through the main body of the capacitor 121 are formed in the direction perpendicular to the main surfaces of the dielectric layers and electrode layers. In the interior surface of the through holes, through hole conductors are formed. Electrode terminals drawn from both end faces of the through-hole conductors are each formed in the main surface on one side (upper main surface) and in the main surface of the other side (lower main surface).

In the semiconductor device described above, the electrode terminals of the capacitors 121 can be directly connected to the semiconductor integrated circuit chip 260 through the solder pads 122. As a result, the resistance of the connection portions can be suppressed to a low level. In addition, because no routing is necessary, connections with low inductance can be made.

This enables rapid charge transfer between the semiconductor integrated circuit chip 260 and the capacitors 121 mounted on the wiringboard, allowing the capacitors 121 to absorb voltage variations that occur when a large amount of high frequency current flows in the semiconductor integrated circuit chip 260, so that malfunctions due to instability of the power supply voltage of the semiconductor integrated circuit chip 260 can be prevented.

While one capacitor 121 is disposed in each of the cavities 120 in the structure of the wiring board described so far, it is possible to dispose a plurality of capacitors 121 by increasing the bottom area of each cavity 120.

For example, by forming the bottom surface of the cavity 120 into the form of a long groove in plan view, a plurality of the capacitors 121 can be aligned.

Although the embodiments of this invention have been described, the present invention is not limited to the above-mentioned embodiments. For example, in the configuration of the laminated thin film capacitor of the present invention, the number of the electrode layers 2, the electrode layers 4 and the thin film dielectric layers is not limited to the above-mentioned examples.

Although the bump shape shown in the figures is desirable as the shape of the terminal units 5, 6, 15 and 16, the invention is not limited to the bump shape.

### WORKING EXAMPLE 1

The laminated thin film capacitor of the same shape as shown in FIG. 7 in which the terminal units 15 and 16 have 16 terminals in total (eight terminals in each of two rows) was produced. The electrode layers 12 and 14 and the terminal base layers 15Y and 16Z were formed by using a DC sputtering equipment and the thin film dielectric layers 13 were formed by using a RF sputtering equipment.

Firstly, a bonding layer made of titanium oxide was formed on a sapphire monocrystal substrate having a thickness of 0.25 mm and a Pt electrode layer having a thickness of 80 nm was formed thereon. The electrode layer of one polarity 12a was processed into a pattern by using photolithography.

The thin film dielectric layer 13a made of Ba_{0.5}Sr_{0.5}TiO₃ of 250 nm was formed on the processed electrode layer 12a. Like the electrode layer of one polarity, the dielectric layer 13a was processed into a pattern by using photolithography.

Further, the electrode layer of the other polarity 14a, the thin film dielectric layer 13b, the electrode layer of one polarity 12b, the thin film dielectric layer 13c, the electrode layer of the other polarity 14b, the thin film dielectric layer 13d and the electrode layer of one polarity 12c were sequentially formed and then patterned to generate the laminated thin film capacitor having four thin film dielectric layers and five electrode layers. At this time, in consideration of accuracy of finishing, the periphery of each of the electrode layers 12 and 14 was set to be reduced gradually by 10 μm toward the upper layers from the lowermost electrode layer 12a.

Next, a basic layer for forming the terminal units on the electrode layer was formed with a Ni layer of 1.0 μm and a Au layer of 0.1 μm and then processed to a pattern by using photolithography. After that, a silica film of 2.0 μm was formed by using a CVD equipment and then patterned to form a protective film with openings so as to expose a part of the basic layer for forming the terminal units by using photolithography. Subsequently, a photosensitive BCB was coated and then exposed and developed to form the protective film with the openings so as to expose a part of the basic layer for forming the terminal units. Next, by using screen printing technique, a commercially available soldering paste was printed on the openings of the protective film and then reflowed to form a soldering bump. In this manner, the laminated thin film capacitor of the present invention was obtained. This laminated thin film capacitor was used as a sample of the present invention.

According to a similar method, the conventional laminated thin film capacitor in which the electrode layers each have a uniform peripheral shape was obtained. This laminated thin film capacitor was used as a comparative sample.

(1) Table 1 summarizes results of a high-temperature loading test for each sample. The high-temperature loading test was performed under the condition of 125° C. and 3.75 V and 1,000 hours and 24 units. Insulation resistance was measured under the condition of the application of a voltage of 2.5 V for 60 seconds at room temperature.

TABLE 1

| | Electrostatic | Insulation | Insulation | Insulation | Insulation | Insulation |
|---|---|---|---|---|---|---|
| | capacitance | resistance | resistance | resistance | resistance | resistance |
| | before test | before test | after test | after test | after test | rate of change |
| | Average | Average | Average | Maximum | Minimum | Average |
| | nF | MΩ | MΩ | MΩ | MΩ | % |
| Sample of the | 152 | 6527 | 901 | 2783 | 302 | 19.9 |
| present | | | | | | |
| invention 1 | | | | | | |
| Comparative | 160 | 3748 | 13 | 119 | 1 | 0.9 |
| sample 1 | | | | | | |

For electrostatic capacitance, there was no substantial change before and after the loading test in both of the samples. A slightly larger capacitance in the comparative sample is due to the difference in an opposed area of the electrode layers.

Insulation resistance before the loading test was a bit larger in the sample of the present invention than in the comparative sample. Moreover, the difference became prominent in insulation resistance after the loading test, revealing that the sample of the present invention was superior to the comparative sample.

As apparent from Table 1, the laminated thin film capacitor of the present invention has a higher initial insulation resistance and is more resistant to deterioration of insulation resistance than the conventional one.

(2) Table 2 summarizes results of a humidity loading test for each sample. The humidity loading test was performed under the condition of 85° C. and 85% and 2.5 V and 1,000 hours and 24 units. Insulation resistance was measured under the condition of the application of a voltage of 2.5 V for 60 seconds at room temperature.

TABLE 2

| | Electrostatic | Insulation | Insulation | Insulation | Insulation |
|---|---|---|---|---|---|
| | capacitance | resistance | resistance | resistance | resistance |
| | before test | before test | after test | after test | after test |
| | Average | Average | Average | Maximum | Minimum |
| | nF | GΩ | MΩ | MΩ | MΩ |
| Sample of the | 151 | 9.70 | 7.54 | 19.02 | 3.85 |
| present | | | | | |
| invention 2 | | | | | |
| Comparative | 160 | 8.60 | 0.06 | 0.17 | 0.02 |
| sample 2 | | | | | |

For electrostatic capacitance, there was no substantial change before and after the humidity loading test in both of the samples.

There was no substantial difference between both samples in insulation resistance before the loading test. Moreover, the difference became prominent in insulation resistance after the loading test, revealing that the sample of the present invention was superior to the comparative sample.

As apparent from Table 2, the laminated thin film capacitor of the present invention is more resistant to deterioration of insulation resistance than the conventional one since the protective film prevents humidity from penetrating.

### WORKING EXAMPLE 2

The laminated thin film capacitor of the same shape as shown in FIGS. 8(a) and 8(b) was produced. The electrode layers 2 and 4 were formed by using a DC sputtering equipment and the thin film dielectric layers 3 were formed by using a RF sputtering equipment.

Firstly, a bonding layer made of titanium oxide was formed on a sapphire monocrystal substrate having a thickness of about 0.25 mm and a Pt electrode layer having a thickness of about 60 nm was formed thereon. The electrode layer of one polarity 2a was processed into a predetermined pattern by using photolithography.

The thin film dielectric layer made of Ba_{0.5}Sr_{0.5}TiO₃ having a thickness of about 250 nm was formed on the processed electrode layer 2a. Like the electrode layer, the dielectric layer 3a was processed into a predetermined pattern by using photolithography.

Further, the Pt electrode layer of the other polarity 4a, the thin film dielectric layer 3b, the Pt electrode layer of one polarity 2b and the thin film dielectric layer 3c were sequentially formed and processed to a pattern.

An Au electrode layer of 300 nm was formed as the electrode layer of the other polarity 4b which is an uppermost electrode layer. Like the other electrode layers, the electrode layer of the other polarity 4b was processed into a predetermined pattern by using photolithography to generate the laminated thin film capacitor having three thin film dielectric layers and four electrode layers.

Next, a terminal electrode layer 8 was formed with a Ni layer having a thickness of about 1.0 μm and a Au layer having a thickness of about 0.1 μm and then processed to a predetermined pattern by using photolithography. After that, a photosensitive BCB was coated and then exposed and developed to form the protective film 7 with the openings so as to expose a part of the terminal electrode layer 8 for forming the terminal units 5 and 6. Next, by using screen printing technique, a commercially available soldering paste was printed on the openings of the protective film and then reflowed to form a soldering bump as the terminal units 5 and 6. In this manner, the laminated thin film capacitor of the present invention was obtained. This laminated thin film capacitor was used as a sample of the present invention.

According to a similar method, a plurality of laminated thin film capacitors that the thickness of the Pt electrode layer, the thickness of the Au electrode layer as an uppermost electrode layer and the number of the dielectric layers are different from each other were obtained.

The frequency characteristic of impedance for each sample was evaluated and ESR was measured by using a measuring device made by Hewlett-Packard, Ltd. (HP4291A). The results were summarized in Table 3.

TABLE 3

| | | | Number of | |
|---|---|---|---|---|
| | Pt | | laminated | |
| | thickness | Au thickness | dielectric | |
| Sample | (nm) | (nm) | layers | ESR (Ω) |
| 1 | 60 | 300 | 3 | 0.11 |
| 2 | 60 | 400 | 3 | 0.08 |
| 3 | 60 | 200 | 3 | 0.15 |
| 4 | 60 | 100 | 3 | 0.23 |
| 5 | 60 | 50 | 3 | 0.32 |
| 6 | 80 | 300 | 3 | 0.10 |
| 7 | 60 | 400 | 6 | 0.07 |
| 8 | 60 | 50 | 6 | 0.20 |

From the results in Table 3, it turned out that ESR could be controlled within a large range of 0.07Ω to 0.32Ω by varying the film thickness of the electrode layers subtly.

### WORKING EXAMPLE 3

The laminated thin film capacitor of the same shape as shown in FIGS. 9(a) and 9(b) was produced. The electrode layers 2 and 4 were formed by using a DC sputtering equipment and the thin film dielectric layers 3 were formed by using a RF sputtering equipment.

Firstly, a bonding layer made of titanium oxide was formed on a sapphire monocrystal substrate having a thickness of 0.25 mm and a Pt electrode layer having a thickness of 60 nm was formed thereon. The electrode layer of one polarity 2a was processed into a predetermined pattern by using photolithography.

The thin film dielectric layer made of Ba_{0.5}Sr_{0.5}TiO₃ having a thickness of 250 nm was formed on the processed electrode layer 2a. Like the electrode layer, the dielectric layer 3a was processed into a predetermined pattern by using photolithography.

Further, the Pt electrode layer of the other polarity 4a, the thin film dielectric layer 3b, the Pt electrode layer of one polarity 2b and the thin film dielectric layer 3c were sequentially formed and processed to a pattern. An Au electrode layer of 300 nm was formed as the electrode layer of the other polarity 4b which is an uppermost electrode layer. Like the other electrode layers, the electrode layer of the other polarity 4b was processed into a pattern by using photolithography to generate the laminated thin film capacitor having three thin film dielectric layers and four electrode layers.

Next, a terminal electrode layer 8 was formed with a Ni layer having a thickness of 1.0 μm and a Au layer having a thickness of 0.1 μm and then processed to a pattern by using photolithography. After that, a photosensitive BCB was coated and then exposed and developed to form the protective film 7 with the openings so as to expose a part of the terminal electrode layer 8 for forming the terminal units. Next, by using screen printing technique, a commercially available soldering paste was printed on the openings of the protective film and then reflowed to form a soldering bump as the terminal units 5 and 6. In this manner, the laminated thin film capacitor was obtained. This laminated thin film capacitor was used as a sample 11.

Next, after the dielectric layer 3c was processed into a pattern according to a similar method, an Au electrode layer of X nm as a difference between the film thickness of the electrode layer 4bb and that of the electrode layers 4ba and 4bc was formed and like the other electrode layers, it was processed into a predetermined pattern by using photolithography. Subsequently, an Au electrode layer of Y nm as the thinner film thickness of either the electrode layer 4bb or the electrode layers 4ba and 4bc was formed and like the other electrode layers, it was processed into a predetermined pattern by using photolithography to generate the laminated thin film capacitor having three thin film dielectric layers and four electrode layers. Furthermore, the protective film 7 and the terminal units 5 and 6 were formed by using a similar method to obtain some laminated thin film capacitors of the present invention, each of which has the different film thickness of the uppermost electrode layer. These laminated thin film capacitors were used as samples 12 to 14. Relations of film thicknesses X, Y of the samples 12 to 14 are summarized in Table 4.

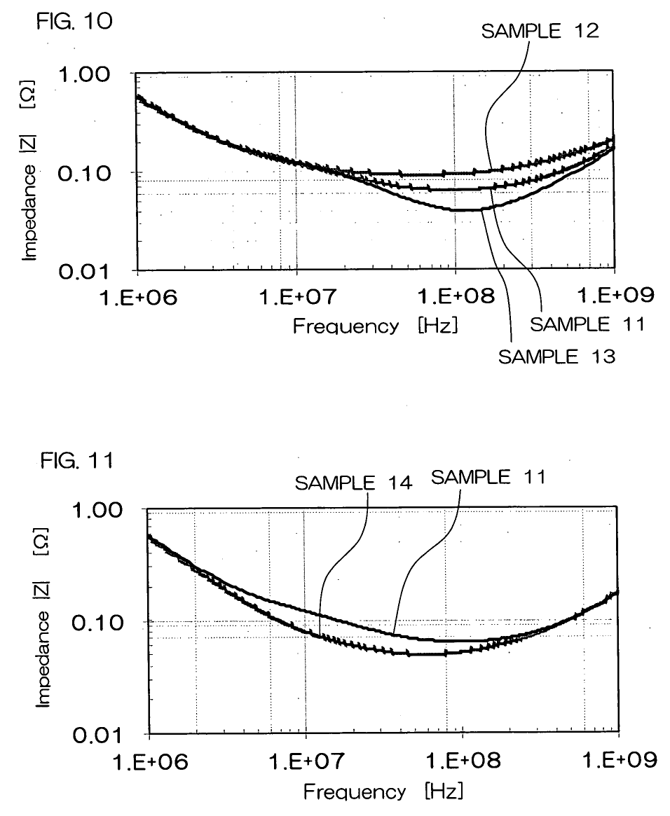

The frequency characteristic of impedance for each sample was evaluated and ESR was measured by using a measuring device made by Hewlett-Packard, Ltd. (HP4291A). The results were summarized in FIGS. 10 and 11.

TABLE 4

| | | | | Electrode | Electrode |
|---|---|---|---|---|---|
| | Film | | Film | layers | layer 4bb |
| Sam- | thickness | | thickness | 4ba, 4bc | thickness |
| ple | X (nm) | Pattern | Y (nm) | thickness (nm) | (nm) |
| 12 | 150 | FIG. 2(g) | 150 | 300 | 150 |
| 13 | 300 | FIG. 2(f) | 300 | 300 | 600 |
| 14 | 300 | FIG. 2(g) | 300 | 600 | 300 |

FIG. 10 shows results the impedance characteristics of the samples 11 to 13. A horizontal axis represents frequency (Hz) and a vertical axis represents impedance (Ω). The thickness of the uppermost electrode layer 4bb in the central capacitance-generating region b, of the samples 11 to 13 is varied to be 300 nm, 150 nm and 600 nm, respectively.

FIG. 11 shows the impedance characteristics of the samples 11 and 14 of the same scale as in FIG. 10. The thickness of the uppermost electrode layers 4ba and 4bc in the capacitance-generating regions a and c located at the left and right, of the samples 11 and 14 is varied to be 800 nm and 600 nm, respectively.

In this manner, the impedance characteristic at the high-frequency side could be controlled by varying the thickness of the uppermost electrode layer 4bb in the central capacitance-generating region b and the impedance characteristic at the low-frequency side could be controlled by varying the thickness of the uppermost electrode layers 4ba and 4bc in the left and right capacitance-generating regions a and c.

Moreover, the impedance characteristic could be controlled to be constant at a higher value (0.1Ω in FIG. 10) in the sample 12 than the sample 11 and the impedance characteristic could be controlled to be constant at a lower value (0.05Ω in FIG. 11) in the sample 14 than the sample 11.

As described above, by controlling the thickness of the uppermost electrode layers independently, the impedance characteristic or ESR characteristic could be controlled.

The disclosure of Japanese patent application No. 2003-205166, filed on Jul. 31, 2003 and Japanese patent application No. 2003-205167, filed on Jul. 31, 2003 is incorporated herein by reference.

What is claimed is:

1. A laminated thin film capacitor in which an electrode layer of one polarity and an electrode layer of the other polarity are alternately laminated on a supporting substrate with a thin film dielectric layer being sandwiched therebetween comprising:
a first terminal unit that connects the electrode layers of one polarity to each other and a second terminal unit that connects the electrode layers of the other polarity to each other,
wherein a layout region of one electrode layer of any two electrode layers constituting the electrode layers of one polarity is encompassed in a layout region of the other electrode layer, and
a layout region of one electrode layer of any two electrode layers constituting the electrode layers of the other polarity is encompassed in a layout region of the other electrode layer.

2. The laminated thin film capacitor as stated claim 1, wherein among the electrode layers constituting the electrode layers of one polarity, a layout region of an electrode layer arranged further from the supporting substrate is encompassed in a layout region of an electrode layer arranged closer to the supporting substrate.

3. The laminated thin film capacitor as stated claim 2, wherein among the electrode layers constituting the electrode layers of the other polarity, a layout region of an electrode layer arranged further from the supporting substrate is encompassed in a layout region of an electrode layer arranged closer to the supporting substrate.

4. The laminated thin film capacitor as stated claim 1, wherein among the electrode layers constituting the electrode layers of one polarity, a layout region of an electrode layer arranged closer to the supporting substrate is encompassed in a layout region of an electrode layer arranged further from the supporting substrate.

5. The laminated thin film capacitor as stated claim 4, wherein among the electrode layers constituting the electrode layers of the other polarity, a layout region of an electrode layer arranged closer to the supporting substrate is encompassed in a layout region of an electrode layer arranged further from the supporting substrate.

6. The laminated thin film capacitor as stated claim 1, wherein given that a thickness of an electrode layer is “t”, t and a distance “a” between the periphery of the electrode layer of one polarity and the periphery of the other electrode layer of the same polarity that is adjacent to the former electrode layer satisfy the following relationship:
20 t≦a≦400 t.

7. The laminated thin film capacitor as stated claim 1, wherein a thickness “d” of the thin film dielectric layer and the thickness “t” of the electrode layer satisfy the following relationship:
3 t≦d.

8. The laminated thin film capacitor as stated claim 1, wherein each electrode layer constituting the electrode layers of one polarity has a first extended part that partially extends beyond the thin film dielectric layer and the first terminal unit is connected to these first extended parts, and
each electrode layer constituting the electrode layers of the other polarity has a second extended part that partially extends beyond the thin film dielectric layer and the second terminal unit is connected to these second extended parts.

9. The laminated thin film capacitor as stated claim 1, wherein within each electrode layer constituting the electrode layers of one polarity, the first terminal unit is connected to the electrode layer, and
within each electrode layer constituting the electrode layers of the other polarity, the second terminal unit is connected to the electrode layer.

10. The laminated thin film capacitor as stated claim 1, further comprising a protective film that coats the thin film dielectric layer and openings so as to expose the first terminal unit and the second terminal unit.

11. The laminated thin film capacitor as stated claim 1, wherein an uppermost electrode layer among the electrode layers has a smaller volume resistivity than the other electrode layers.

12. The laminated thin film capacitor as stated claim 11, wherein the uppermost electrode layer has a volume resistivity of 3.0×10⁻⁸ Ωm or less under 100° C. and the other electrode layers have a volume resistivity ranging from 10.0×10⁻⁸ Ωm to 20.0×10⁻⁸ Ωm under 100° C.

13. The laminated thin film capacitor as stated claim 1, further comprising three capacitance-generating regions where an electrode layer of one polarity and an electrode layer of the other polarity are alternately laminated on a supporting substrate with a thin film dielectric layer being sandwiched therebetween,
wherein the three capacitance-generating regions are arranged at the center and left and right thereof at predetermined intervals, and
a thickness of the uppermost electrode layer of the central capacitance-generating region among the three capacitance-generating regions is different from that of the uppermost electrode layers of the left and right capacitance-generating regions.

14. The laminated thin film capacitor as stated claim 13, where the thickness of the uppermost electrode layer of the central capacitance-generating region among the three capacitance-generating regions is larger or smaller than that of the uppermost electrode layers of the left and right capacitance-generating regions by 10%.

15. A semiconductor apparatus comprising the laminated thin film capacitor as stated in claim 1, wherein an electrical terminal is formed on the laminated thin film capacitor, and a semiconductor chip is connected to the electrical terminal.
